(19) United States
(12) Patent Application Publication
(10) Pub. No.: US 2015/0117668 A1
(43) Pub. Date: Apr. 30, 2015

(54) AIRPLANE SEAT, AUDIO SYSTEM, AND AIRPLANE

(71) Applicant: LUFTHANSA TECHNIK AG, HAMBURG (DE)

(72) Inventor: Frank Niss, Hamburg (DE)

(21) Appl. No.: 14/406,332

(22) PCT Filed: Jun. 5, 2013
(86) PCT No.: PCT/EP2013/001639

§ 371 Date: Dec. 8, 2014

(30) Foreign Application Priority Data
Jun. 6, 2012 (DE) 10 2012 209 563.2

(51) Int. Cl. B64D 11/00; H03G 3/00; H04R 1/02

(52) U.S. Cl. CPC B64D 11/00154; H04R 1/02; H03G 3/00
USPC 381/86

(57) ABSTRACT

The invention relates to an airplane seat having an audio system for playing back audio data, wherein the audio system comprises a volume controller and/or a noise compensation controller, a head rest element having a loudspeaker element that can be swiveled at a swivel angle α, and wherein the volume and/or the degree of noise compensation is controlled subject to the swivel angle α.

### BACKGROUND OF INVENTION

The invention relates to an airplane seat having an audio system for playing back audio data having the features of the preamble of claim 1, an audio system having the features of the preamble of claim 2 or claim 5, and a corresponding airplane having the features of the preamble of claim 10.

On medium-haul and long-haul flights, airplanes are usually equipped with in-flight entertainment systems which provide the passengers with audio and video data during the flight.

For this purpose, the passengers are usually provided with headsets via which the audio data is converted into sound and thus is played back.

Open loudspeakers are not suitable for use in the airplane since with the use of such open loudspeakers, the passengers would be disturbed by their seatmates.

The main reason for this is the fact that the loudspeakers would have to be set to a very high sound volume during the flight so as to drown out the loud background noises of the engines in the cabin.

However, some passengers find the headsets annoying. The audio cables as well as the constant contact on or in the ears can be found annoying and unpleasant.

In addition, during each flight, the headsets have to be laboriously distributed and collected again.

It is therefore an object of the invention to provide an airplane seat, an audio system for playing back audio data, and a corresponding airplane by means of which the aforementioned problems are reduced.

### BRIEF SUMMARY

This object is achieved by the invention with the features of the independent claims. Thus, for achieving the object, an airplane seat having an audio system for playing back audio data is proposed, wherein the audio system comprises a volume controller and/or a noise compensation controller as well as a head rest element having a loudspeaker element that can be swiveled at a swivel angle α, wherein the volume and/or the degree of noise compensation is/are controlled as a function of the swivel angle α.

This means that the volume is controlled such that, for example, it is higher or lower depending on the position into which the loudspeaker element is swiveled. In one embodiment, the volume at a certain swivel angle α can be zero and can adopt an audible intensity only upon reaching a different swivel angle α.

The audio system can comprise a volume controller or a noise compensation controller; however, in a preferred configuration of the invention, both controllers are provided.

Thus, according to the invention, on the one hand an audio system for an airplane seat for playing back audio data, having a volume controller and a head rest element, is proposed, wherein the head rest element comprises at least one loudspeaker element that can be swiveled at a swivel angle α, and the volume of the played back audio data is controlled by the volume controller as a function of the swivel angle α.

Moreover, according to the invention, an audio system for an airplane seat for playing back audio data, having a noise compensation controller and a head rest element, is proposed which comprises at least one microphone and at least one loudspeaker element that can be swiveled at a swivel angle α, and wherein the degree of noise compensation is controlled as a function of the swivel angle α.

Such a control of the volume and/or the noise compensation as a function of the swivel angle α makes it possible to configure the playback of the audio data in such a manner that it is audible only to the target recipient, and neighboring passengers are not disturbed by the playback.

Noise compensation is to be understood as destructive interference of sound. A so-called “anti-sound” is applied to the ears of the passenger. This anti-sound is preferably a 180 degree phase-shifted audio signal of the noise level at the ears of the passenger.

The degree of noise compensation is to be understood as the strength of the anti-sound signal. This means that, for example, a stronger or weaker anti-sound signal is generated, depending on the position into which the loudspeaker element is swiveled. In one embodiment, the noise compensation at a certain swivel angle α can be zero, and can be switched on only upon reaching a different swivel angle α. The degree of noise compensation can also be viewed as the difference in the sound pressure level, for example. Thus, in the case of a low degree of noise compensation, for example, only a few decibels of noise are compensated within a certain frequency range, whereas at a higher degree of noise compensation, more decibels are compensated.

Noise compensation ensures that the passenger hears the airplane noise to a significantly lesser degree, and the passenger thus has the impression that the airplane is quieter. In order to determine the level and frequency of the anti-sound, microphones are preferably provided on the head rest element. The microphones are situated close to the passenger's ears.

A plurality of airplane seats according to the invention are preferably situated next to one another. Thus, according to the invention, an airplane having a first airplane seat and a second airplane seat situated next thereto is also proposed, wherein the first and the second airplane seats are configured as described above, and wherein the audio system of the first airplane seat is configured to adjust the volume and/or the noise compensation of the audio data in such a manner that the played back audio data is substantially audible only to the passenger in the first airplane seat.

In addition, the audio system of the second airplane seat can be correspondingly configured. Accordingly, the audio system of the second airplane seat is preferably configured to adjust the volume and/or the noise compensation in such a manner that the played back audio data is substantially audible only to the passenger in the second airplane seat.

The term “substantially audible only to the passenger in the first airplane seat” means that, although under certain circumstances the seatmate is able to perceive individual playback fragments, they are so soft for the seatmate that he/she does not feel disturbed. The background noises during the flight clearly drown out the played back audio data so that it is hardly perceivable by the seatmate, although it would be normally understandable during a standstill of the engines. The playback of the audio signals is preferably controlled by the audio system such that the volume of the played back audio data in the region of the ears of the seatmate is lower than 8 sones (70 phons). The volume is preferably controlled to be lower than 5.65 sones (65 phons), more preferably lower than 2.83 sones (55 phons).

Moreover, the volume and/or the noise compensation of the audio system of the first seat can preferably be controlled as a function of the position of the loudspeaker elements of the second seat. If, for example, the seatmate in the second airplane seat also has completely folded in the loudspeaker elements, an increased volume at the first airplane seat is less disturbing for him/her, so that the audio system of the first seat permits or provides a comparatively increased volume.

The audio system of the first airplane seat is preferably configured to use the audio data intended for playback at the second airplane seat for the noise compensation and/or volume control. The audio signals intended for output at the neighboring airplane seat can, for example, be retrieved digitally and used for generating the anti-sound. Transmission of the audio data from the second airplane seat to the first airplane seat can take place electrically or optically. Furthermore, it is advantageous when further neighboring seats transmit their audio data intended for output to the audio system of the first seat. These can be, for example, the neighboring seats to the right and left of the first airplane seat. In possible embodiments, the audio data of the neighboring seat in the front and/or the rear can also be transmitted to the first airplane seat.

In this manner, the anti-sound can be attuned considerably more precisely to the ambient noises, in particular to the playback at the neighboring seat, since no feedback or recording of the audio data played back at the second airplane seat is required. In contrast to the background noises such as the engine noise, for example, the audio data of the second airplane seat intended for playback is known in the system and therefore can be used in a targeted manner for considerably improving the noise compensation for the passenger in the first seat. In this manner, disturbance by a seatmate who, for example, listens to music or watches a movie can be minimized.

In addition to transmitting the audio signal, further data that can be used for optimizing noise compensation is advantageously transmitted. The further data can comprise the instantaneous swivel angle α and/or the set volume level of the second airplane seat or the neighboring seats. Furthermore, information about the distance and/or direction of the neighboring seats can be associated with the transmitting audio data, as a result of which the acoustic travel time and a delay in the noise compensation can be precisely determined, which can additionally improve the noise compensation of the playback of the neighboring seat. In further possible embodiments, the delay and the noise compensation in a stereo operation can be separately determined for the right and left audio data of a neighboring seat. This is advantageous in particular in the case of a closely spaced seat arrangement, since the right and left loudspeaker elements of a second airplane seat have a proportionally highly deviating distance from a closely spaced first airplane seat. Due to the constellation in an airplane, the direction from which a disturbing playback of a neighboring seat arrives at a first airplane seat also remains constant. Thus, the delays of an anti-sound signal for compensating the playback of a neighboring seat can be different for a right and a left loudspeaker element of an airplane seat. If this concerns, for example, the audio data of a second airplane seat that is situated to the right of a first airplane seat, the anti-sound signal can be delayed longer at the left loudspeaker element than at the right loudspeaker element of the first airplane seat.

The dependency of the volume control and/or noise compensation control on the swivel angle α comprises a number of preferred configurations. For example, at a swivel angle α=0, thus, when the loudspeaker element is completely folded out, the playback can be switched off. As soon as the swivel angle α is greater than zero or, for example, exceeds a predetermined threshold angle α, the volume or the noise compensation is started.

The volume and/or the degree of the noise compensation of the played back audio data is/are preferably increased with increasing swivel angle α. Thus, the volume or the noise compensation is increased as a function of the angle α; folding in the loudspeaker element results in a louder or clearer signal. Due to the noise compensation, preferably the low-frequency broadband disturbing noises of the airplane engines are compensated so that audio signals having a higher frequency can be better perceived. Audio sources, which are directed increasingly directly toward the ears of the passenger with increasing swivel angle α are arranged in the swivelable loudspeaker element.

Due to the accurate alignment of the audio sources with the ears of the passenger, it is possible to increase the volume to a greater extent without disturbing neighboring passengers. It is preferred that the audio system comprises two swivelable loudspeaker elements. The loudspeaker elements are then arranged on both sides of the passenger's head, and enclose it increasingly when the swivel angle increases.

The maximum volume and/or the highest noise compensation is/are preferably set at a swivel angle α≈90°. This means that in no other position of the loudspeaker elements does a higher volume or a greater noise compensation take place. The loudspeaker element or the loudspeaker elements is/are then aligned parallel to the passenger's ears and facing one another. Due to this position, the audio playback is most clearly perceivable by the passenger, and the signal is still weaker for neighboring passengers since they are then located completely on the side of the loudspeaker element facing away from the audio source.

The volume and/or the degree of noise compensation of the played back audio data is/are preferably continuously or steadily increased with increasing swivel angle α. In alternative embodiments, increasing the volume and/or the degree of noise compensation can take place in steps with increasing swivel angle, wherein preferably at least three, more preferably at least four, steps are provided, so that the increase at least appears to the passenger as being continuous with increasing swivel angle α.

In further advantageous embodiments, the volume is not increased further at a swivel angle α=45° or greater, more preferably at a swivel angle α=60° or greater, or is even decreased again in possible embodiments. The volume can appear to the passenger as still increasing, since the distance from the loudspeaker element to the ear of the passenger becomes significantly shorter with increasing swivel angle α.

The swivelable loudspeaker element preferably comprises a padded surface which is arranged over the audio source situated in the loudspeaker element and therefore covers the audio source, and which is permeable to the sound emitted by the audio source. The padded surface preferably includes soft padded elements which make resting the head comfortable; however, the padded surface is preferably also permeable, for example perforated, so that the sound emitted by the audio source can easily pass through it.

Moreover, it is preferred that the audio system is configured to adjust the volume and/or the noise compensation for announcements of the captain or the aircrew so that the announcements become particularly clearly and precisely understandable. For example, any in-flight entertainment media can be paused and/or the audible engine noise can be additionally reduced by the noise compensation.

### BRIEF DESCRIPTION OF DRAWINGS

The invention is explained hereafter by means of preferred embodiments with reference to the attached figures. In the figures:

FIG. 1 shows a front view of three airplane seats according to the invention which are arranged next to each other;

FIG. 2a shows a top view of a completely opened head rest element;

FIG. 2b shows a top view of a head rest element that is halfway opened;

FIG. 2c shows a top view of a closed head rest element;

FIG. 3a shows a front view of the opened head rest element from FIG. 2a; and

FIG. 3c shows a front view of the closed head rest element from FIG. 2c.

### DETAILED DESCRIPTION

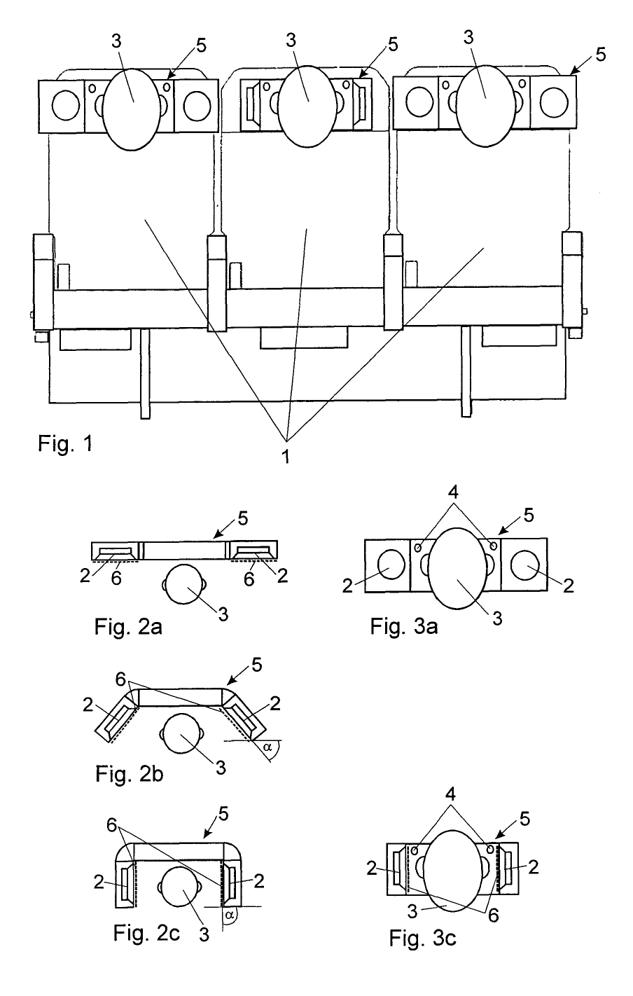

FIG. 1 illustrates three airplane seats 1 which are arranged next to each other. An airplane usually has a multiplicity of such seating groups which, as an alternative, can also comprise two, four or more airplane seats 1. According to the invention, the airplane seats each have a head rest element 5.

The head rest element 5 is part of an audio system; in the middle airplane seat 1 it is illustrated in the closed state, and in each of the outer airplane seats 1 it is shown in the open state.

Audio data is played back for the passengers during the flight via the audio system. Controlling the volume of the audio data takes place via a volume controller. In addition, the audio system comprises a controller for noise compensation via which the loud background noises are to be reduced during the flight.

The different positions of the head rest element 5 are illustrated in FIGS. 2a to 2c and in FIGS. 3a and 3c. The head rest element 5 has two swivelable loudspeaker elements 2, each of which contains an audio source for converting the audio data into sound. The head rest element 5 also has two microphones 4 which are arranged laterally at the passenger's head and through which preferably noise information is collected for the noise compensation.

Depending on the position of the loudspeaker elements 2, a different swivel angle α is assumed. In the completely opened state illustrated in FIGS. 2a and 3a, the swivel angle α=0°. In the completely closed state illustrated in FIGS. 2c and 3c, the swivel angle α≈90°. The position of the loudspeaker elements 2 is preferably symmetrical, so that both loudspeaker elements 2 automatically assume the same swivel angle α when one of the two is shifted.

Accordingly, the swivel angle α between these end positions assumes values between 0° and 90°. Depending on the swivel angle, the noise compensation and the volume are controlled to different levels. In the closed position in FIGS. 2c and 3c, the noise compensation and the volume are set to the maximum, whereas in the folded-out state in FIGS. 2a and 3a, the playback is switched off. Accordingly, the engine noises during the flight are compensated the most in the closed position.

As soon as the passenger wants to start the audio playback, folding in the loudspeaker elements 2 will start the playback or increase the volume.

Folding in takes place manually; however, it can also take place via corresponding buttons or controllers. In one configuration of the invention, for this purpose the loudspeaker elements 2 are provided with electrical actuators via which the swivel movement is possible via remote control.

Padded surfaces 6 are situated on the inner sides of the loudspeaker elements 2 facing the passenger's head 3. The padded surfaces 6 are arranged over audio sources in the loudspeaker element, thus, over the region in which the audio data are converted into sound that is audible to the passenger.

The padded surfaces 6 on the one hand serve as a head rest for the passenger so that, for example, he/she can lean his/her head against the padded surface. However, the padded surfaces 6 are also permeable to sound, and for this purpose they are perforated, for example, or are formed as a spacer fabric and/or spacer textile so that they combine the function of a pad and a membrane which is permeable to sound.

### LIST OF REFERENCE NUMERALS

1 airplane seat
2 loudspeaker element
3 passenger's head
4 microphone
5 head rest element
6 padded surface

1-32. (canceled)

33. An airplane, comprising:
a first airplane seat and a second airplane seat arranged next thereto,
wherein the first airplane seat comprises a first audio system for playing back first audio data,
wherein the first audio system comprises a first volume controller and/or a first noise compensation controller as well as a first head rest element having a first loudspeaker element that can be swiveled at a first swivel angle α₁,
wherein a first volume and/or a first degree of a first noise compensation is/are controlled as a function of the first swivel angle α₁,
wherein the second airplane seat comprises a second audio system for playing back second audio data,
wherein the second audio system comprises a second volume controller and/or a second noise compensation controller as well as a second head rest element having a second loudspeaker element that can be swiveled at a second swivel angle α₂,
wherein a second volume and/or a second degree of a second noise compensation is/are controlled as a function of the second swivel angle α₂,
wherein the first audio system of the first airplane seat is configured to adjust the first volume and/or the first noise compensation of the first audio data such that the played back first audio data is substantially audible only to a first passenger in the first airplane seat,
wherein the first audio system of the first airplane seat is configured to use the second audio data intended for playback at the second airplane seat for first noise compensation and/or first volume control.

34. An airplane, comprising:
a first airplane seat and a second airplane seat arranged next thereto,
wherein the first airplane seat comprises a first audio system for playing back first audio data, wherein the first audio system comprises a first volume controller and/or a first noise compensation controller as well as a first head rest element having a first loudspeaker element that can be swiveled at a first swivel angle α₁,
wherein a first volume and/or a first degree of a first noise compensation is/are controlled as a function of the first swivel angle α₁,
wherein the second airplane seat comprises a second audio system for playing back second audio data,
wherein the second audio system comprises a second volume controller and/or a second noise compensation controller as well as a second head rest element having a second loudspeaker element that can be swiveled at a second swivel angle α₂,
wherein a second volume and/or a second degree of a second noise compensation is/are controlled as a function of the second swivel angle α₂,
wherein the first audio system of the first airplane seat is configured to adjust the first volume and/or the first noise compensation of the first audio data such that the played back first audio data is substantially audible only to a first passenger in the first airplane seat,
wherein the second audio system of the second airplane seat is configured to adjust the second volume and/or the second noise compensation such that the played back second audio data is substantially audible only to a second passenger in the second airplane seat,
wherein the first audio system of the first airplane seat is configured to use the second audio data intended for playback at the second airplane seat for first noise compensation and/or first volume control.

35. The airplane according to claim 33,
wherein the first audio system comprises the first volume controller,
wherein the first volume is controlled as a function of the first swivel angle α₁,
wherein the second audio system comprises the second volume controller,
wherein the second volume is controlled as a function of the second swivel angle α₂,
wherein the first audio system of the first airplane seat is configured to use the second audio data intended for playback at the second airplane seat for first, volume control.

36. The airplane according to claim 35,
wherein the second audio system of the second airplane seat is configured to adjust the second volume such that the played back second audio data is substantially audible only to a second passenger in the second airplane seat.

37. The airplane according to claim 36,
wherein the first volume is increased with increasing first swivel angle α₁, wherein the second volume is increased with increasing second swivel angle α₂.

38. The airplane according to claim 37,
wherein a maximum first volume is set at a first swivel angle α₁≈90°,
wherein a maximum second volume is set at a second swivel angle α₂≈90°.

39. The airplane according to claim 33,
wherein the first audio system comprises the first noise compensation controller,
wherein the first degree of the first noise compensation is controlled as a function of the first swivel angle α₁,
wherein the second audio system comprises the second noise compensation controller,
wherein the second degree of the second noise compensation is controlled as a function of the second swivel angle α₂,
wherein the first audio system of the first airplane seat is configured to use the second audio data intended for playback at the second airplane seat for first noise compensation.

40. The airplane according to claim 39,
wherein the second audio system of the second airplane seat is configured to adjust the second noise compensation such that the played back second audio data is substantially audible only to a second passenger in the second airplane seat.

41. The airplane according to claim 40,
wherein the first degree of first noise compensation is increased with increasing first swivel angle α₁,
wherein the second degree of second noise compensation is increased with increasing second swivel angle α₂.

42. The airplane according to claim 41,
wherein a maximum first noise compensation is set at a first swivel angle α₁≈90°,
wherein a maximum second noise compensation is set at a second swivel angle α₂≈90°.

43. The airplane according to claim 40,
wherein the first head rest element comprises at least one first microphone,
wherein the second head rest element comprises at least one second microphone.

44. The airplane according to claim 33,
wherein the first audio system comprises the first volume controller and the first noise compensation controller,
wherein the first volume and the first degree of the first noise compensation are controlled as a function of the first swivel angle α₁,
wherein the second audio system comprises the second volume controller and the second noise compensation controller,
wherein the second volume and the second degree of the second noise compensation are controlled as a function of the second swivel angle α₂,
wherein the first audio system of the first airplane seat is configured to use the second audio data intended for playback at the second airplane seat for first noise compensation and first volume control.

45. The airplane according to claim 44,
wherein the second audio system of the second airplane seat is configured to adjust the second volume and the second noise compensation such that the played back second audio data is substantially audible only to a second passenger in the second airplane seat.

46. The airplane according to claim 45,
wherein the first head rest element comprises at least one first microphone,
wherein the second head rest element comprises at least one second microphone.

47. The airplane according to claim 45,
wherein the first volume is increased with increasing first swivel angle α₁,
wherein the second volume is increased with increasing second swivel angle α₂,
wherein the first degree of first noise compensation is increased with increasing first swivel angle α₁,
wherein the second degree of second noise compensation is increased with increasing second swivel angle α₂.

48. The airplane according to claim 47,
wherein a maximum first volume is set at a first swivel angle α₁≈90°,
wherein a maximum second volume is set at a second swivel angle α₂≈90°,
wherein a maximum first noise compensation is set at a first swivel angle α₁≈90°,
wherein a maximum second noise compensation is set at a second swivel angle α₂≈90°.

49. The airplane according to claim 45,
wherein the first head rest element comprises an additional first loudspeaker element,
wherein the second head rest element comprises an additional second loudspeaker element,
wherein the first head rest element comprises two first microphones,
wherein the two first microphones collect first noise information for the first noise compensation,
wherein the second head rest element comprises two second microphones,
wherein the two second microphones collect second noise information for the second noise compensation.

50. The airplane according to claim 33,
wherein the first head rest element comprises an additional first loudspeaker element,
wherein the second head rest element comprises an additional second loudspeaker element.

51. The airplane according to claim 33,
wherein the first loudspeaker element comprises a first padded surface, wherein the first padded surface is arranged over a first audio source that is situated in the first loudspeaker element, wherein the first padded surface is permeable to sound emitted by the first audio source,
wherein the second loudspeaker element comprises a second padded surface, wherein the second padded surface is arranged over a second audio source that is situated in the second loudspeaker element, wherein the second padded surface is permeable to sound emitted by the second audio source.

52. The airplane according to claim 51,
wherein the first audio system comprises an additional first loudspeaker element,
wherein the additional first loudspeaker element comprises an additional first padded surface, wherein the additional first padded surface is arranged over an additional first audio source that is situated in the additional first loudspeaker element, wherein the additional first padded surface is permeable to sound emitted by the additional first audio source,
wherein the second audio system comprises an additional second loudspeaker element,
wherein the additional second loudspeaker element comprises an additional second padded surface, wherein the additional second padded surface is arranged over an additional second audio source that is situated in the additional second loudspeaker element, wherein the additional second padded surface is permeable to sound emitted by the additional second audio source.
